(19) United States
(12) Patent Application Publication
(10) Pub. No.: US 2006/0156108 A1
(43) Pub. Date: Jul. 13, 2006

(54) Method for testing semiconductor chips using check bits

(76) Inventors: Patric Stracke, Muenchen (DE); Udo Hartmann, Neuried (DE); Jochen Kallscheuer, Heuden (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/287,606

(22) Filed: Nov. 28, 2005

(30) Foreign Application Priority Data
Nov. 29, 2004 (DE) 10 2004 057 484.7

(51) Int. Cl. G01R 31/28

(52) U.S. Cl. 714/724

(57) ABSTRACT

A method for testing semiconductor chips is disclosed. A chip to be tested has a test logic, at least one test mode is set in the form of a serial first bit string, the test modes are executed in the chip and test results or the status of the test modes are output from the chip in the form of a serial second bit string. The method includes at least one of the bit strings is provided with at least one binary check bit, the test logic being controlled by a check bit which is in a first logic state such that the bits of the bit string which follow the check bit are skipped until a check bit which is in the second logic state is detected by the test logic. The test logic is controlled by a check bit which is in the second logic state such that the bits of the bit string which follow the check bit are not skipped until a check bit which is in the first logic state is detected by the test logic.

### CROSS-REFERENCE TO RELATED APPLICATIONS

This Utility Patent Application claims priority to German Patent Application No. DE 10 2004 057 484.7 filed on Nov. 29, 2004, which is incorporated herein by reference.

### FIELD OF THE INVENTION

The present invention lies in the technical field of the fabrication of semiconductor chips, in particular memory chips, and relates to a method for testing semiconductor chips in which, in a chip to be tested, a plurality of test modes are set by means of a serial bit string, the test modes are executed and test results or the status of the test modes are subsequently output by means of a serial bit string.

### BACKGROUND

An essential part of the fabrication of semiconductor chips, in particular memory chips, is testing the quality of the fabricated chip. In the context of quality assurance, tests are often carried out simultaneously on a multiplicity of chips as early as at the wafer level, in order to segregate defective chips or to be able to initiate corresponding repair measures as early as possible.

In modern chipmaking, in customary test methods by means of a tester a multiplicity of test modes are set (loaded) into the chip(s) to be tested and are executed and the test results are output to the tester. In this case, the test modes may be stored in the respective tester; chips are often also equipped with a corresponding test logic in which, inter alia, various test modes may also be stored.

Nowadays test modes are usually set in the chip to be tested via a serial interface with the aid of a bit string in which respective bit sequences are in each case allocated to a specific test mode. By means of the bit string, the test modes are activated/deactivated, for example, or specific parameters are set in a respective test mode, whereby a test mode can be altered or, by way of example, specific subfunctions of a test mode can be activated/deactivated. In this case, a complete bit string is always transmitted serially, said bit string including the bit sequences of all the test modes even if only a specific test mode is to be executed or changed.

On account of the ever more complex structure of the chips which accompanies advancing miniaturization, ever more extensive tests have to be performed with regard to the required quality assurance. However, this has the effect that the serially supplied bit strings generally become very long and the setting or changing of individual or a plurality of test modes accordingly takes up very much time and, under certain circumstances, may even become time-critical. This problem occurs primarily when one or more test modes are changed over multiply during a test, which in practice may indeed be the case several thousand times per test. This means in practice that owing to time problems tests can often only be carried out inadequately or not at all, with the result that it is necessary to reckon with an increased rate of inefficient chips that have reached the market. Furthermore, the very long bit strings required for complex chip structures cannot be handled by all test systems, since the bit width of all the registers in a test system is limited with regard to hardware. This can lead to significant overhead times in production.

Against this background, the object of the present invention is to specify a method for testing semiconductor chips, in particular memory chips, which makes it possible to effect the setting or changing of test modes or the control of test mode functions and the read-out of the test results or of the status of test modes by the use of serial bit strings more rapidly or in a shorter period of time than in the case of the conventional method.

### SUMMARY

The present invention provides a method for testing semiconductor chips. In one embodiment, the method for testing semiconductor chips includes providing a chip to be tested which has a test logic, at least one test mode is set in the form of a serial first bit string, the test modes are executed in the chip and test results or the status of the test modes are output from the chip in the form of a serial second bit string. At least one of the bit strings is provided with at least one binary check bit, the test logic being controlled by a check bit which is in a first logic state such that the bits of the bit string which follow the check bit are skipped until a check bit which is in the second logic state is detected by the test logic, and the test logic being controlled by a check bit which is in the second logic state such that the bits of the bit string which follow the check bit are not skipped until a check bit which is in the first logic state is detected by the test logic.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A schematically illustrates an exemplary embodiment of a method according to the invention.

FIG. 1B schematically illustrates a method for comparison with the exemplary embodiment of a method according to the invention from FIG. 1C.

FIG. 1C schematically illustrates an exemplary embodiment of a method according to the invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

In one embodiment, the invention provides a method for testing semiconductor chips, in particular memory chips, in which, in a chip which is equipped with a test logic and is to be subjected to a test, at least one test mode, generally a plurality of test modes, is set in the form of a serially supplied first bit string. The test modes are executed in the chip, and test results or the status of test modes (or else values of trimming test modes) are output from the chip in the form of a second serial bit string. In this embodiment, both the first bit string and the second bit string are composed of a succession of binary bits, it being possible for bit sequences of a bit string to be assigned to at least one test mode or at least one test mode function. The first bit string may also be used as the second bit string if the corresponding bits have been set in the header of the bit string, that is to say that the first and second bit strings may also be identical.

The method according to the invention is distinguished, then, by the fact that at least one of the two bit strings, that is to say first and/or second bit string, is provided with at least one binary check bit.

For the case where the binary check bit is in a first one of its two logic states (the check bit is not “set”), which is represented, e.g., by the logic value “0”, the check bit has the effect that the test logic skips the bits of the relevant bit string which follow said check bit until the test logic detects a further check bit of the relevant bit string which is in the other, second, logic state, represented, e.g., by the logic value “1”.

On the other hand, for the case where the binary check bit is in the second one of its two logic states (the check bit is “set”), this check bit has the effect that the test logic does not skip the bits of the relevant bit string which follow the check bit and reads them in until the test logic detects a further check bit of the bit string which is in the other, first logic state.

With the aid of the method according to the invention, it is thus advantageously possible to subdivide the entire bit string into a plurality of bit sequences with the aid of check bits, the bits of the respective bit sequences, depending on the logic state of their preceding check bits, being skipped by the test logic or being read in by the test logic and output as test result or as status of test modes (or as values of trimming test modes). In other words, only the bits of the bit sequences with a set check bit are read into the test logic, while the bits of the bit sequences with a non-set check bit are not read into the test logic, so that only determined or determinable test modes or test mode functions can be controlled without all the bits of the complete bit string having to be read into the test logic. Equally, when outputting test results or the status of test modes (or the values of trimming test modes), it is possible to set only those check bits which are associated with those bit sequences of the test modes or test mode functions for which the test results or the status of test modes (or values of trimming test modes) are intended to be output.

Since the bits of the bit sequences with the non-set check bits can be skipped by the test logic both during the inputting and during the outputting of the bit strings, it is thus possible, in an extremely advantageous manner, to save time when setting/changing (controlling) test modes, when controlling test mode functions or when outputting test results/status of test modes (values of trimming test modes). In particular, this makes it possible to control determined or determinable test modes/test mode functions in a targeted manner and to output the test results or the status of test modes (or values of trimming test modes).

According to one embodiment of the invention, it may be advantageous if only the first bit string, that is to say the bit string which is fed serially to the test logic for the control of test modes/test mode functions, is provided with check bits for controlling the test logic. Furthermore, it may be advantageous for additionally or solely the second bit string for serially outputting the test results or the status of test modes (or the values of trimming test modes) to be provided with check bits for controlling the test logic.

In one embodiment of a method according to the invention, the bit sequences preceded by a check bit may be assigned to one or more test modes, in which case it may be advantageous for the bits of a bit sequence preceded by a check bit to be assigned only to an individual test mode. The test modes can be activated/deactivated by the bits of the bit sequences assigned to them. It is equally possible for parameters of the test modes to be changed by the bits of the bit sequences assigned to the test modes, whereby specific functions may be changed or specific subfunctions may be activated/deactivated.

Furthermore, in one embodiment of the method according to the invention, the bit sequences preceded by a check bit may be assigned to one or more test mode functions, in which case it may be advantageous for the bits of a bit sequence preceded by a check bit to be assigned only to an individual test mode function. The test mode functions can be activated/deactivated by the bits of the bit sequences assigned to them. It is equally possible for the test mode functions to be changed thereby.

In one embodiment of the method according to the invention, it may furthermore be advantageous for a check bit to precede the first and/or second bit string, which may have the effect that the bits of the complete bit string, depending on whether or not the check bit is set, are read in by the test logic or skipped by the test logic. This may prove to be advantageous, for example, if a plurality of different bit strings are transmitted all at once serially to the chip to be tested, or a plurality of different bit strings are output all at once by the chip, but only individual ones thereof are intended to be taken into account. In this case, the check bit may precede a header bit sequence identifying the bit string.

According to one embodiment of the invention, a check bit may furthermore precede all the bit sequences of a bit string which are assigned to at least or precisely one test mode. Equally, a check bit may precede all the bit sequences of a bit string which are assigned to at least or precisely one test mode function.

In one embodiment of the method according to the invention, it is thus possible for a complete bit string to be preceded by a check bit, which has the effect that the bits of the bit string, depending on whether or not the check bit is set, are read into/out of the test logic or are skipped by the test logic. Furthermore, one, a plurality or all of the bit sequences which may be assigned to at least one or an individual test mode may be preceded by a check bit, which has the effect that the bits of the bit sequences, depending on whether or not the check bit is set, are read into/out of the test logic or are skipped by the test logic. Furthermore, one, a plurality or all of the bit sequences which may be assigned to at least one or only one individual test mode function may be preceded by a check bit, which has the effect that the bits of the bit sequences, depending on whether or not the check bit is set, are read into/out of the test logic or are skipped by the test logic. In the case of the last-mentioned measure, the expression “test mode functions” is also intended to encompass test mode subfunctions, that is to say further differentiations of test mode functions, which are also test mode functions in the actual sense.

The above subdivision of the complete bit string into ever smaller bit sequences each preceded by a check bit thus enables test modes or test mode functions to be controlled in a targeted manner by setting only the check bits of the associated bit sequences. This subdivision of the bit string into ever smaller bit sequences is limited, however, from the standpoint of saving time during the serial transmission of the bit string between a test apparatus and the chip to be tested, to the effect that at least one bit of a bit sequence can be skipped by the test logic. In this respect, it makes no sense for each bit of a bit string to be preceded by a set check bit since this does not give rise to a time saving compared with the conventional serial transmission of a bit string. In other words, a bit sequence which is assigned to a test mode or a test mode function should contain at least two bits.

The method according to the invention is not restricted in any regard whatsoever in terms of its application. It shall be mentioned merely as an example that voltages or electric currents can be trimmed by means of the method according to the invention.

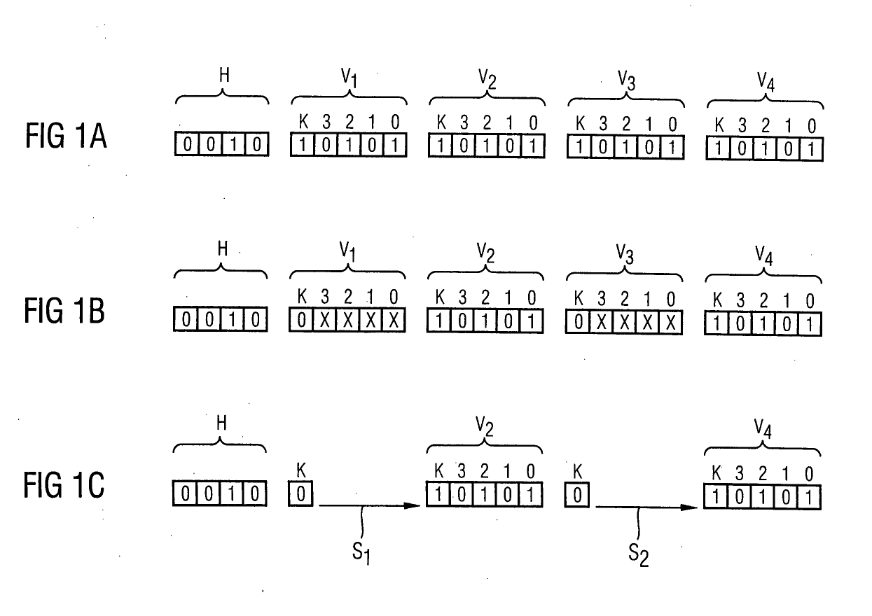

Reference shall be made to FIG. 1A, which illustrates an exemplary embodiment of a method according to the invention when applied to the trimming of four different voltages. Thus, FIG. 1A illustrates a bit string composed of a header H and four different bit sequences V₁, V₂, V₃ and V₄, which are assigned to four different voltages, voltage 1 to voltage 4, the four different voltages being intended to be trimmed. In this embodiment, each of the bit sequences V₁, V₂, V₃ and V₄ is composed of four binary bits 0, 1, 2, 3 and a preceding check bit K. In the exemplary embodiment of FIG. 1A, all the check bits of the four bit sequences V₁, V₂, V₃ and V₄ are set, that is to say have e.g. the logic value “1”, so that the bits of the respective bit sequence which follow a check bit are read into the test logic. Mutually corresponding bits of the different bit sequences V₁, V₂, V₃ and V₄ have the same logic states, whereby a trimming of the four different voltages is intended to be achieved. On account of the bit length, 24 clock cycles are required for reading in the bit string of FIG. 1A. Since all the check bits are set in the bit string of FIG. 1A, no bits are skipped by the test logic, so that no time saving is afforded during the serial transmission of the bit string by comparison with a conventional method. In the method of FIG. 1B, only the differences with respect to the exemplary embodiment according to the invention from FIG. 1A will be explained in order to avoid unnecessary repetition. In this method, only two voltages are intended to be trimmed and the two remaining voltages are intended to be left unchanged. For this purpose, the check bits of the bit sequences V₁ and V₃ are not set (logic state “0”), which has the effect that the corresponding voltages are not altered or reset. In this method, it shall be assumed that when a check bit is not set, the test logic does not skip the bits that follow the non-set check bit. Accordingly, 24 clock cycles are required for transmitting the bit string of FIG. 1B. A time saving during the transmission of the bit string cannot be achieved by comparison with the conventional method.

In FIG. 1C, only the differences with respect to the method of FIG. 1B will be explained in order to avoid unnecessary repetition. In this embodiment, likewise only two voltages are intended to be trimmed and the two remaining voltages are intended to be left unchanged. For this purpose, the check bits of the bit sequences V₁ and V₃ are not set (logic stage “0”), which has the effect that the corresponding voltages are not altered or reset. In this method, the non-set check bits have the effect according to one embodiment of the invention that when a check bit is not set, the test logic skips the bits which follow the non-set check bit. This has the effect that the test logic jumps (S₁) from the non-set check bit K of the bit sequence V₁ assigned to the first voltage 1 to the set check bit K of the bit sequence V₂ assigned to the second voltage 2 and subsequently reads in the bits of the second bit sequence V₂. The test logic thereupon jumps from the non-set check bit K of the bit sequence V₃ assigned to the third voltage 3 to the set check bit of the bit sequence V₄ assigned to the fourth voltage and reads in the bits of the fourth bit sequence V₄, whereby a voltage trimming of the second and fourth voltages is effected on account of the identical logic states of the second and fourth bit sequences. In the method of FIG. 1C, a total of 16 cycles are required for the transmission of the bit string, so that there is a time saving by comparison with a conventional method.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for testing semiconductor chips, comprising:
providing a chip to be tested which has a test logic, at least one test mode is set in the form of a serial first bit string, the test modes are executed in the chip and test results or the status of the test modes are output from the chip in the form of a serial second bit string; and
providing at least one of the bit strings with at least one binary check bit, the test logic being controlled by a check bit which is in a first logic state such that the bits of the bit string which follow the check bit are skipped until a check bit which is in the second logic state is detected by the test logic, and the test logic being controlled by a check bit which is in the second logic state such that the bits of the bit string which follow the check bit are not skipped until a check bit which is in the first logic state is detected by the test logic.

2. The method of claim 1, comprising:
providing the first and the second bit string with at least one check bit.

3. The method of claim 1, comprising:
providing a check bit preceding a bit sequence of the bit string which is assigned to at least one test mode.

4. The method of claim 1, comprising:
providing a check bit preceding a bit sequence of the bit string which is assigned to an individual test mode.

5. The method of claim 1, comprising providing a check bit preceding a bit sequence of the bit string which is assigned to at least one test mode function.

6. The method of claim 1 comprising: providing a check bit preceding a bit sequence of the bit string which is assigned to an individual test mode function.

7. The method of claim 1, comprising:
providing a check bit preceding at least one of the bit strings.

8. The method of claim 1, comprising:
providing a check bit preceding all of the bit sequences which are assigned to at least one test mode.

9. The method of claim 1, comprising:
providing a check bit preceding all of the bit sequences which are assigned to an individual test mode.

10. The method of claim 1, comprising:
using a bit sequence assigned to a test mode is used to activate or deactivate this test mode.

11. The method of claim 1, comprising:
using a bit sequence assigned to a test mode or test mode function to set parameters of this test mode.

12. A method for testing semiconductor memory chips comprising:
providing a memory chip to be tested having a test logic, at least one test mode is set in the form of a serial first bit string, the test modes are executed in the chip and test results or the status of the test modes are output from the chip in the form of a serial second bit string; and
providing at least one of the bit strings with at least one binary check bit, the test logic being controlled by a check bit which is in a first logic state such that the bits of the bit string which follow the check bit are skipped until a check bit which is in the second logic state is detected by the test logic, and the test logic being controlled by a check bit which is in the second logic state such that the bits of the bit string which follow the check bit are not skipped until a check bit which is in the first logic state is detected by the test logic.

13. The method of claim 12, comprising:
providing the first and the second bit string with at least one check bit.

14. The method of claim 13, comprising:
providing a check bit preceding a bit sequence of the bit string which is assigned to at least one test mode.

15. The method of claim 13, comprising:
providing a check bit preceding a bit sequence of the bit string which is assigned to an individual test mode.

16. The method of claim 13, comprising:
providing a check bit preceding a bit sequence of the bit string which is assigned to at least one test mode function.

17. The method of claim 13, comprising:
providing a check bit preceding a bit sequence of the bit string which is assigned to an individual test mode function.

18. A method for testing semiconductor memory chips comprising:
providing a memory chip to be tested having a test logic, at least one test mode is set in the form of a serial first bit string, the test modes are executed in the chip and test results or the status of the test modes are output from the chip in the form of a serial second bit string; and
providing at least one of the bit strings with at least one binary check bit, the test logic being controlled by a check bit which is in a first logic state such that the bits of the bit string which follow the check bit are skipped until a check bit which is in the second logic state is detected by the test logic, and the test logic being controlled by a check bit which is in the second logic state such that the bits of the bit string which follow the check bit are not skipped until a check bit which is in the first logic state is detected by the test logic, the method further comprising providing a check bit preceding at least one of the bit strings.

19. The method of claim 18, comprising:
providing a check bit preceding all of the bit sequences which are assigned to at least one test mode.

20. The method of claim 19, comprising:
providing a check bit preceding all of the bit sequences which are assigned to an individual test mode.

21. The method of claim 20, comprising:
using a bit sequence assigned to a test mode is used to activate or deactivate this test mode.

22. The method of claim 20, comprising:
using a bit sequence assigned to a test mode or test mode function to set parameters of this test mode.

23. A method for testing semiconductor chips, comprising:
means for providing a chip to be tested which has a test logic, at least one test mode is set in the form of a serial first bit string, the test modes are executed in the chip and test results or the status of the test modes are output from the chip in the form of a serial second bit string; and
means for providing at least one of the bit strings with at least one binary check bit, the test logic being controlled by a check bit which is in a first logic state such that the bits of the bit string which follow the check bit are skipped until a check bit which is in the second logic state is detected by the test logic, and the test logic being controlled by a check bit which is in the second logic state such that the bits of the bit string which follow the check bit are not skipped until a check bit which is in the first logic state is detected by the test logic.
